(19) United States
(12) Patent Application Publication
(10) Pub. No.: US 2013/0008334 A1
(43) Pub. Date: Jan. 10, 2013

(54) MEMS DETONATOR

(75) Inventors: Robert Claridge, Sevenoaks (GB); David Combes, Malvern (GB)

(73) Assignee: QINETIQ LIMITED, Farnbourgh, Hampshire (GB)

(21) Appl. No.: 13/635,616

(22) PCT Filed: Mar. 3, 2011
(86) PCT No.: PCT/GB11/00283

§ 371 Date: Sep. 17, 2012

(30) Foreign Application Priority Data
Mar. 16, 2010 (GB) 1004276.0
Aug. 4, 2010 (GB) 1013057.3

(51) Int. Cl. F42B 3/10; H05K 13/00; F42B 3/198

(52) U.S. Cl. 102/202.5; 29/592.1

(57) ABSTRACT

This invention relates to a MEMS detonator, in particular the production of MEMS scale detonators via the use of a microreactor (3). The invention further lies in a reproducible manufacturing method of MEMS scale detonators, for use in safety and arming units (SAU), which are used in warheads and munitions. A warhead comprising a MEMS detonator may find particular use in increasing the IM compliance of munitions. The method involves the use of high pressure input of two solutions (2, 2a) into a microreactor (3) to form an in-situ precipitation reaction, which furnishes an initiatory (i.e. primary) explosive, wherein the explosive and supernatant liquid is directly fed into a microchamber, using the microcavities in the septum as a MEMS sieve to retain the explosive and form a MEMS detonator.

This invention relates to the production of micro-electromechanical system (MEMS) scale detonators, in particular their production via the use of microreactors. The invention further lies in a reproducible method of manufacture of a MEMS scale detonator for use in miniature safety and arming units that may be employed in warheads and munitions. In particular, the invention lies in the field of improved insensitive munition (IM) warheads, especially those capable of providing a reduced response to hazard stimuli such as fragment or bullet attack. A warhead fitted with a safety and arming unit (SAU) comprising a MEMS detonator will find particular use in increasing the IM compliance of munitions. There is further provided a kit suitable for preparing such a warhead. There is a requirement to provide warheads with increased IM compliance.

By the term “munition” as used herein is meant any casing that carries a detonable i.e. a high explosive material, typically in the form of a warhead. The munition may also comprise other energetic materials that are used to deliver said warhead, such as bombs, rockets, or any similar device.

According to a first aspect of the invention, there is provided a MEMS detonator comprising a substrate comprising at least one microchamber filled with an explosive material, wherein said at least one microchamber comprises a first end which is capable of receiving said explosive material and a second end comprising a septum containing a plurality of fully perforated microcavities, and wherein at least one igniter is located proximate to the explosive material. Preferably, the igniter is a heater wire, and is located in thermal contact with the explosive material. Typically, but not necessarily, the first and second ends form opposing sides of the microchamber.

The microchamber preferably contains an explosive material consolidated to at least 30% of its theoretical maximum density, preferably to at least 40% theoretical maximum density, more preferably in the range of from 60 to 95% theoretical maximum density (TMD). Preferably, the explosive material is a particulate explosive material.

By explosive material is meant a material that gives a high energetic output, most preferably a detonative output. The energetic output in the design mode of a MEMS detonator must be capable of initiating the explosive train, typically a high explosive.

The explosive material housed in the microchamber may be a pyrotechnic, high explosive, propellant or initiatory material. In a preferred embodiment of the invention, the production of a MEMS detonator requires the use of an initiatory compound, usually one that is capable of forming a detonative output. Typically, initiatory compounds are capable of being ignited and propagate to detonation, rather than requiring a detonative input source. Initiatory compounds are usually very sensitive to stimuli (shock, electrical spark, friction and so on) and so are often avoided. However, the reduced size of a MEMS detonator arrangement means that the chances of being struck by a fragment or being subjected to shock are significantly reduced compared to conventional SAU detonators, which mitigates the usual sensitivity associated problems of using initiatory compounds.

The microchamber which houses the explosive material preferably has a diameter in the range of from 100 to 1500 microns, more preferably in the range of from 500 to 1000 microns. The plurality of microcavities in the septum preferably each have a diameter in the range of from 10 to 100 microns, and more preferably in the range of from 20 to 50 microns. The microcavities are used to extract the carrier fluid from the microchamber in the filling method defined hereinafter. In the method, the first end can be considered to be an input region for the microchamber and the second end, which houses the septum, can be considered to be an output region.

The substrate may be any material that is compatible with the explosive material that is selected. The substrate is conveniently selected from materials which are capable of being processed by MEMS manufacturing techniques, such as, for example, silicon, glass or nickel. The use of a silicon or glass wafer enables subsequent integration by means of wafer bonding with other components fabricated on wafers.

The at least one igniter may be located at the first or second end of the microchamber. Preferably, the igniter is located distal to the septum and, in a more preferred arrangement, the at least one igniter is located at the first end of the substrate such that the septum forms a flyer plate to assist in the detonation transfer from the detonator to the explosive train.

The igniter may be a single device or may be comprised of multiple igniter devices each capable of providing an output capable of igniting the explosive material in the microchamber. The igniter may be any suitable igniter such as, for example, a resistance wire, a semiconductor bridge device, an electric fuse, a laser igniter, an exploding flyer initiator, an exploding bridgewire detonator or an ignition system based on a reactive intermetallic system (RIMS). (A RIMS typically comprises alternate layers of intermetallic materials, such as, for example, titanium and carbon, which are sputtered onto a wire. Resistive heating induces a chemical reaction in the RIMS to produce a hot particulate output, which can cross air gaps and ignite the energetic material.) The igniter may be designed to provide an igniferous output under a relatively low firing voltage, preferably below 50V.

In a preferred arrangement, the igniter is a resistance wire, typically in thermal contact with the explosive material. The resistance wire may be deposited by any known metal deposition technique, such as those commonly used in the manufacture of printed circuit boards (PCBs).

In an arrangement whereby the microchamber and the explosive material contained therein are to be moved in and out of line of the at least one igniter, the at least one igniter is preferably selected such that it is capable of igniting the explosive material across a small air gap, so that it does not need to be in direct thermal contact with the explosive material. A RIMS igniter would be suitable for this purpose.

In a highly preferred arrangement, the MEMS detonator exploits the use of a flyer plate as part of the detonative output, which assists transfer of the detonation wave from the MEMS detonator to the rest of the explosive train. Therefore, if the igniter is located at the first end of the microchamber, at the end distal to (typically opposite to) the septum, then the explosive output will transfer away from the igniter towards the septum (which contains the microcavities) and hence, the septum forms a flyer plate.

In an alternative embodiment, the septum containing the microcavities may be removed from the substrate and the igniter may be located at either the first or second end of the microchamber. Preferably, an additional flyer plate may be located at the end distal to the igniter.

According to a second aspect of the invention, there is provided a method of preparing a primary explosive comprising the steps of:
i) selecting two or more solutions that are capable of interacting to form an explosive material as a precipitate,
ii) passing the two or more solutions in separate channels into a microreactor,
iii) causing the combining and/or mixing of the two or more solutions,
iv) causing precipitation of said explosive material.

In other words, the method according to the second aspect involves; selecting two or more solutions which, when combined, interact to form an explosive material as a precipitate; passing the two or more solutions in separate channels into a microreactor; and combining and/or mixing the two or more solutions in the microreactor so that precipitation takes place. The solution may need to be mixed using mixing means, or the act of combining the solutions may cause mixing to occur. (For example, turbulence effects of combining two solutions may cause mixing to occur.)

The microreactor may be the microchamber described in the first aspect of the invention. Preferably, however, the microreactor is separate from the microchamber.

According to a third aspect of the invention, there is provided a method of filling a MEMS detonator according to the first aspect comprising the steps of:
i) selecting two or more solutions that are capable of interacting to form an explosive material as a precipitate,
ii) passing the two or more solutions in separate channels into a microreactor,
iii) causing the combining and/or mixing of the two or more solutions,
iv) causing precipitation of said explosive material, and
v) depositing said precipitate into a microchamber comprising a septum containing a plurality of microcavities, and allowing the supernatant solution to pass through the microcavities.

In other words, the method according to the third aspect involves; selecting two or more solutions which, when combined, interact to form an explosive material as a precipitate; passing the two or more solutions in separate channels into a microreactor; combining and/or mixing the two or more solutions in the microreactor so that precipitation takes place; passing the precipitate and supernatant fluid into a microchamber comprising a septum containing a plurality of microcavities such that the precipitate is deposited in the microchamber; and allowing the supernatant fluid to pass through the microcavities.

The microcavities in the septum provide a MEMS scale sieve arrangement to trap the precipitated explosive material within the microchamber and allow the typically aqueous supernatant solution to pass through the microcavities. The septum may optionally be removed after the microchamber has been filled, or the microcavities may be filled with a curable filler, so as to enhance the septum's ability to act as a flyer. Typically, the precipitated explosive material is a particulate material.

The reaction conditions in the microreactor may be varied. For example, at the mixing and combining stage it may be desirable that the reaction is undertaken at an elevated temperature and/or increased pressure, to ensure that the reaction goes to completion.

Alternatively, the precipitation of the explosive may be promoted by cooling the reaction mixture, or indeed other commonly used chemistry techniques may be employed to induce crystallisation or precipitation of the reaction product.

In a preferred method of the invention, the two or more solutions are a first solution of a non-explosive compound and a second solution of a non-explosive compound, which when combined in the microreactor undergo a chemical reaction to form an explosive material. Preferably, the chemical reaction is a chemical precipitation reaction. The precipitation reaction may be carried out in aqueous or organic solvents. The precipitation reaction may be a result of the formation of ionic bonds, chelation or the formation of covalent bonded structures. In a preferred embodiment, the two or more solutions are different aqueous ionic salts which when mixed together undergo a chemical precipitation reaction to provide an explosive material which is a non aqueous-soluble salt. An example of a precipitation reaction may be one in which the reactants exchange ions to form an insoluble salt, that is one that does not dissolve in water. The preferred aqueous ionic salts may comprise organic or inorganic counter ions, or a chelating reaction product.

A further advantage of using a microreactor to synthesise the explosive material in-situ is that it reduces the need for handling explosive material, prior to its synthesis. The skilled chemist would be able to readily select the appropriate first and second solutions that are required to form the desired precipitates, such as azides, fulminates or picrates. An example is sodium azide and silver nitrate to form silver azide. In a preferred embodiment, the explosive materials are selected from initiatory (more commonly referred to as primary) explosives, because they require only a small input stimulus and provide a detonative output.

The reactions are not limited to salt formation. However, organic reactions may require longer reactions conditions, produce unwanted side products or require forcing conditions to achieve reaction.

Preferably, the precipitated explosive material is a particulate explosive material, rather than a gelatinous product. Desirably, the particulate explosive material is an explosive non aqueous-soluble salt.

In an alternative embodiment of the invention, the two or more solutions are a first solution of a dissolved explosive material and a second solution of a solvent capable of causing precipitation of the dissolved explosive material from said first solution. In this way, a precipitate of said explosive material is formed when the first and second solutions are combined. For example, tetrazoles or PETN may be caused to precipitate, thereby allowing the MEMS detonator to be readily filled with the organic explosive material. This method may be particularly useful for explosives which are organic compounds that are not as well suited to in-situ synthesis, due to the likely formation of unwanted side products during the course of the reaction.

The extent of the explosive output from an explosive material, and in particular achieving a detonative output from an initiatory/primary explosive, is determined by the level of consolidation and confinement. A loose powder fill of an initiatory material in a microchamber may not permit a detonation reaction to propagate within the explosive material. Pyrotechnic and initiatory materials that are used in munitions are typically consolidated materials, which are prepared by exposing powders to high loading using appropriate tools and presses, to form a pellet of consolidated powder. The use of MEMS scale consolidation tooling is not suitable for reproducible filling techniques. The method according to the invention, however, can prepare consolidated explosive material that is compacted in the microchamber to at least 40% theoretical maximum density, more preferably 60 to 95% theoretical maximum density.

If required, a binder can be used in conjunction with the explosive material, to increase the fill and improve structural integrity within and/or around the plurality of microcavities. The binder may be introduced into the microchamber in any suitable manner, for example by including the binder—as a suspension or otherwise—in at least one of the two or more solutions. A resin or binder may also be used to seal the explosive material at the first end (input) of the microchamber, thereby acting as a barrier to the ignition source.

The two or more solutions may be pumped using simple syringe arrangements. However, in order to achieve the desired range of % TMD, the two or more solutions may be pumped at an elevated pressure, preferably in the range of from 1 to 100 atmospheres, more preferably in the range of from 10 to 40 atmospheres. The use of HPLC (High Performance Liquid Chromatography) pumps provides a useful pump system that is capable of providing reproducible pressures and conditions. A yet further advantage of using two solutions which do not comprise an explosive material, i.e. one in which the explosive is made in-situ, is that the explosive material is not passed through the mechanical pump. This reduces the risk of depositing explosive material in the pump.

The microchambers may be filled with explosive material by use of an automated dispensing system that fills each microchamber in sequence or in parallel, so as to provide a high throughput manufacturing process.

One of the advantages of the use of a MEMS detonator is its very small physical size and its reduced risk of being impacted upon (by incoming fragments). Additionally, greater levels of shielding may be used because free space in a munition is very limited. Therefore, the use of very sensitive primary explosives may be mitigated by the very small size and reduced risk of being impacted upon, compared to conventional low voltage detonator arrangements.

Furthermore, when a MEMS scale detonator forms part of a SAU, the interrupter portion of the SAU (that is, the portion that interrupts detonation propagation to the explosive train and the rest of the output charges) will more easily contain the reduced detonative output from a MEMS scale detonator. Hence, the SAU or the interrupter portion may be smaller, leading to a more compact design. In a further arrangement, the MEMS detonator may be more easily configured to move in and out of line with the explosive train.

A yet further advantage of miniaturisation of detonators facilitates highly miniaturised safety and arming units, which increase the available volume within munitions for other functions such as increased lethality or course correction.

In a yet further embodiment, there may be one or more microchambers which may be arranged in an array, wherein the ignition of the explosive material in each said microchamber is preferably under separate electronic control. Such an array may be used to facilitate multiple modes of detonation, for example deflagration or detonation or directional effects. Such an array may alternatively be used as a digital thruster, in which increments of thrust are provided by igniting gas generative explosive material in each microchamber.

As described previously, a further flyer may be provided on the MEMS detonator according to the invention to enhance its detonative output and thus improve its function as a detonator. The flyer may comprise the septum, or a separate layer which forms a further flyer may be incorporated on top of the explosive filling within the microchamber, or on top of the septum. The further flyer may be comprised of a polymer or metal material such as, for example aluminium, copper or nickel. The further flyer material preferably has a density per unit area of between 0.1 kg/m² and 0.25 kg/m².

The microchamber may be formed by utilising a multi-layer printed circuit board arrangement or prepared from a metallised ceramic circuit board. Electrically conducting tracks may be fabricated, during the manufacturing process, directly onto the inner surface of the microchamber. The electrically conductive tracks may, in use, be supplied with a current to perform the function of a resistance wire and provide an inbuilt thermal igniter, to facilitate ignition of the explosive material deposited thereon.

Printed circuit boards can be readily fabricated with multiple levels, using known techniques. The formation of blind holes, such as, for example, the microchamber which houses the particulate explosive material, may be achieved in multi level printed circuit boards by conventional machining, for example by drilling individual layers of PCBs prior to lamination. Laser micromachining may be used to create very small holes in PCB layers, which may be used to prepare the microcavities in the septum. So, by a combination of conventional machining and laser micromachining in a first level of a PCB, an array of controlled microchambers may be formed, and in a second level a plurality of microcavities may be formed.

In a further embodiment, the MEMS detonator according to the invention may be prepared from a silicon or glass wafer, and thus may be attached to further wafers using a low temperature polymer bond process. The further wafers may comprise other devices such as, for example, firing circuits, power supplies, electronic components such as, for example, igniters, means of activating a safety and arming unit or to cause ignition of the igniter. It may be desirable to use a low temperature bond process to attach the explosive filled microchambers to wafers carrying igniters. The bonding polymer may, for example, be a material such as BCB or SUB. Preferably, the bond is cured at a temperature below 100° C. A low temperature cure system is desirable, and the actual temperature of the process is preferably below the ignition temperature of the explosive material housed in the microchamber.

It will be apparent to one skilled in the art that a range of techniques exist for patterning microchambers, and for providing a septum that contains a plurality of microcavities, and that appropriate techniques depend on a number of factors including the substrate material and the geometry of the required features. Suitable techniques include deep reactive ion etching, electrochemical machining, conventional machining processes, electroforming, etching and laser micromachining.

A protective layer may be applied to the outer surfaces of the substrate material prior to filling the microchambers with explosive material, so as to minimise contamination, typically particulate contamination, of the exposed surface of the substrate. Typically, the protective layer will be provided on the surface distal to the septum. The protective layer is preferably a removable protective layer such as, for example, a removal polymer, one example being a photoresist layer. The protective layer may be removed after filling the microchambers with explosive material, leaving a surface with greatly reduced explosive material and/or dust particle contamination.

It is desirable to prevent contamination of other parts of the SAU from the explosive material. The tolerance of the wafer bond process to particle contamination may be increased by bonding wafers using an adhesive material in which spacer spheres have been incorporated. The spacer spheres preferably have a diameter of between 2 and 50 microns. Adhesive with spheres may be dispensed automatically in an appropriate pattern on one of the substrates to be bonded. The size of the spheres may be selected to accommodate the maximum particle size of any particle contamination present on either of the surfaces to be bonded, such as might result from an explosive fill process according to the invention.

In alternative arrangement, a conducting track may be provided in the bottom of the microchamber to facilitate electrical ignition of the explosive material in the microchamber. Accordingly, there is provided a method of forming a MEMS detonator comprising the steps of:
depositing a first metal layer on a first side of a first silicon wafer,
depositing a first dielectric layer on the first metal layer,
depositing and patterning a second metal layer with a conducting track onto the first dielectric layer,
depositing a second dielectric layer on the second metal layer to encapsulate the conducting tracks, so as to form an encapsulated resistance wire arrangement,
depositing a seed layer for electrochemical plating on the first side of a second wafer,
depositing a resist mould layer suitable for electroforming and of appropriate thickness and patterned on the seed layer to provide microcavities in the subsequent electroformed layer (suitable for enabling the extraction of fluid from a microchamber),
electroforming an appropriate metal flyer layer by plating up from the seed layer in the resist mould to provide a perforated metal layer (i.e. septum),
planarising the electroformed metal layer prior to removal of the resist mould to facilitate subsequent wafer bonding,
etching a microchamber, such as, for example, by deep reactive ion etching, into the second side of the silicon wafer, coincident with the perforations, and
after filling the microchamber, and optional cleaning of surfaces, bonding the first wafer containing the metal conducting tracks, such that the resistance wire is coincident with the microchamber.

The electroformed metal layer may be replaced with a polymer layer with appropriate mechanical properties to function as a flyer, such as, for example, SU8 or polyimide. The polymer may be patterned by photochemical methods, or by reactive ion etching.

Multiple MEMS detonators, including means of ignition for each, according to the invention may be formed on a wafer, and integrated with multiple interrupter devices formed on a wafer by a process of wafer bonding. The integration of miniature detonator devices according to the invention with miniature interrupters results in a highly miniaturised safety and arming unit. The integration of detonators with interrupters at the MEMS level allows many hundreds of devices to be assembled with a high degree of precision at low cost. A MEMS safety and arming unit according to the invention is more compact than would result from using a conventional miniature external detonator device, by allowing a smaller interrupter due to the reduced output of the detonator and by the very small size of the detonator.

The interrupter devices may comprise a stack of multiple wafers patterned using MEMS technology to provide interrupter devices. The interrupter may be suspended on compliant springs such that moving surfaces are not in contact at rest. In this way, the potential for stiction failures in production and in use may be reduced.

According to a fourth aspect of the invention, there is provided a safety and arming unit comprising at least one MEMS detonator according to the invention. An explosive system may comprise a SAU that contains an igniter, an explosive material, optionally a flyer, an interrupter and an explosive train which continues to the final output charge(s). A typical SAU provides a moveable interrupter to prevent detonation transfer from the explosive material to the explosive train.

In an alternative SAU arrangement, the microchamber may be moved in and out of alignment with the igniter and explosive train, such that in an armed position the explosive material filled microchamber is in-line with an igniter and explosive train. When the SAU is in a safe position, the explosive filled microchamber is placed out of line of both the igniter and the explosive train, as the igniter is not capable of initiating the explosive train. In such a way, safety can be achieved in the safe position and detonative transfer and a functional explosive train may readily be achieved in the armed position.

The interrupter device may include at least two interlocks that control the movement of the interrupter from a safe position to an armed position. At least one interlock may be responsive to spin and at least one interlock may be responsive to setback acceleration. Mechanical interlocks responsive to acceleration(s) resulting from launch or spin may be fabricated using MEMS processes and integrated with the interrupter.

A mechanical interlock responsive to spin may include a time delay between the start of the spin and the unlocking of the interlock, to allow safe separation of the munition from the launch mechanism prior to complete unlocking of the interrupter.

Interlocks responsive to electronic control may be fabricated using MEMS processes and integrated with the interrupter. Possible actuation modes are electrostatic actuation, electro thermal actuation and/or piezoelectric actuation, preferably electro thermal actuation. The inclusion of at least one interlock under electronic control facilitates an arming delay under electronic control, enabling a high degree of flexibility in the application of the safety and arming unit.

Suitable interlocks are well known to the skilled person.

According to a fifth aspect of the invention, there is provided a precursor unit for a MEMS detonator comprising a substrate comprising at least one microchamber, wherein said at least one microchamber comprises a first end which is capable of receiving said explosive material and a second end comprising a septum containing a plurality of fully perforated microcavities. The microchamber in the precursor unit can be filled with explosive material by a method as described herein. Preferably, once the microchamber has been filled, the precursor unit is provided with at least one igniter (proximate to the explosive material) to produce a MEMS detonator.

According to a sixth aspect of the invention, there is provided a munition comprising at least one safety and arming unit according to the fourth aspect.

According to a seventh aspect of the invention, there is provided the use of a MEMS detonator according to the first aspect in a munition.

The skilled person will understand that by MEMS is generally meant electromechanical devices and systems which are typically measured in micrometers, and which are built onto substrates such as semiconductor chips. Although the devices typically have dimensions in the order of microns, individual electro and/or mechanical device components may have sub-micron (typically nanometer) dimensions. MEMS fabrication methods are well known to the skilled person.

Any feature in one aspect of the invention may be applied to any other aspects of the invention, in any appropriate combination. In particular, device aspects may be applied to method and use aspects, and vice versa.

Embodiments of the invention are described below by way of example only and with reference to the accompanying drawings in which:

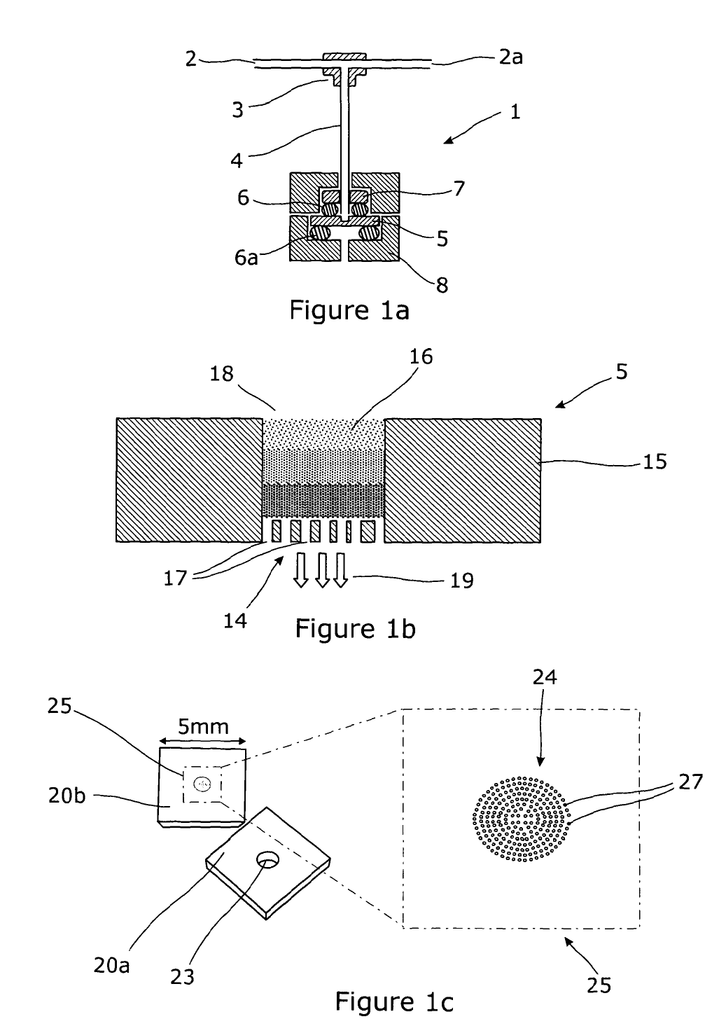

FIGS. 1a, 1b and 1c show respectively a side view of a MEMS microreactor for filling a single MEMS microchamber, a cross-sectional side view close up of the substrate, and a top and rear view of two MEMS tiles;

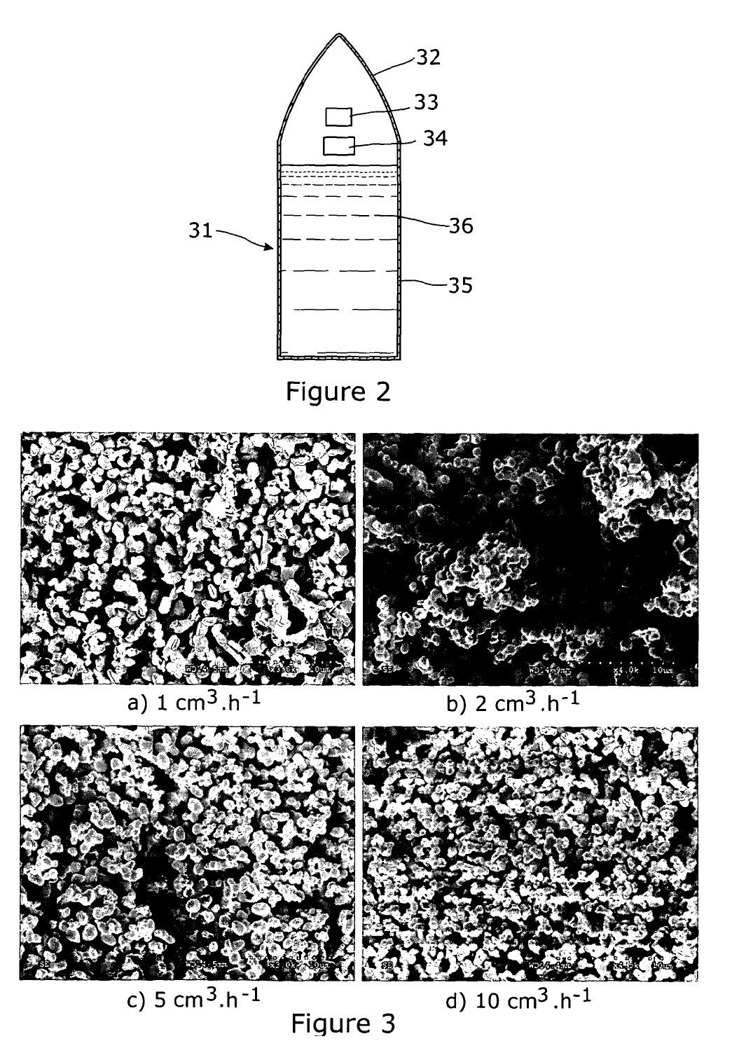

FIG. 2 shows a schematic side view of a munition that comprises a SAU;

FIGS. 3a to 3d show scanning electron micrographs (SEMs) of the formation of silver azide at different flow rates;

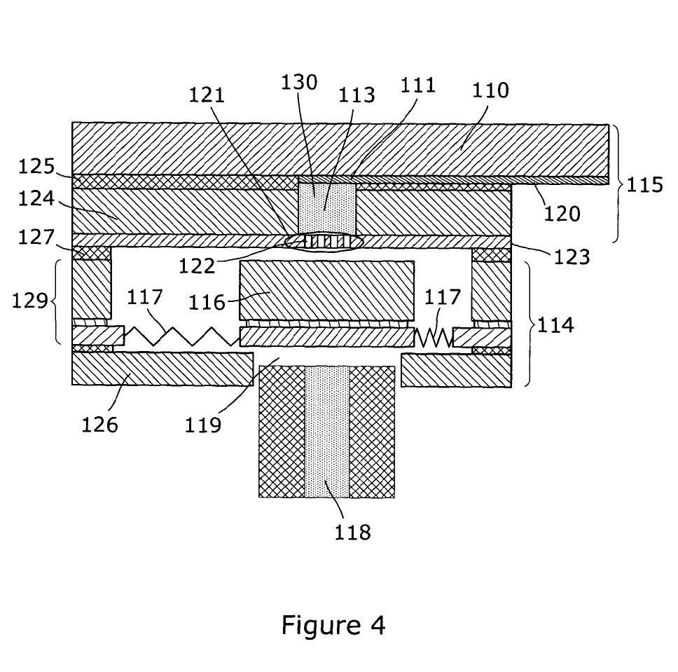

FIG. 4 shows a side schematic view of one arrangement of a safety and arming unit; and

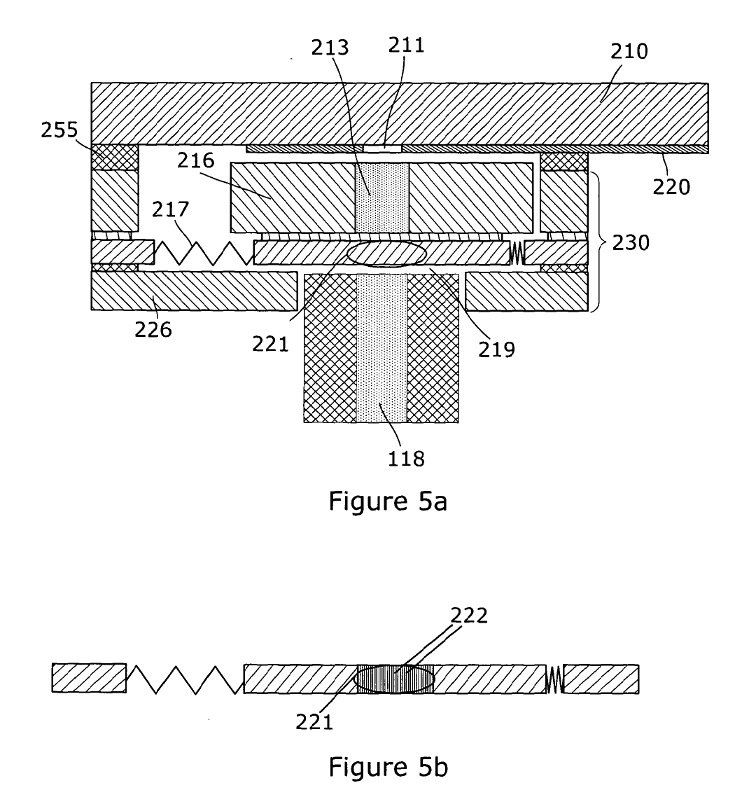

FIGS. 5a and 5b respectively show a side schematic view of an alternative arrangement of a safety and arming unit according to the invention, and a preferred embodiment of the septum.

FIG. 1a shows a side view of a MEMS detonator filling apparatus 1. The apparatus 1 comprises two input tubes 2, 2a which contain the solutions that will provide the precipitation reaction, such as, for example, silver nitrate AgNO₃ and sodium azide NaN_{3.} The solutions are provided under pressure by a pump (not shown) to the microreactor 3. The solutions are combined and mixed in the microreactor 3 and precipitation occurs. The solid precipitate and the suspending liquid (not shown) are still under pressure and travel down the delivery tube 4 to the MEMS tile 5. The delivery tube 4 is held in place by a clamp 7 in the enclosure 8, with respective o-ring seals 6 and 6a ensuring that the only path for the solid precipitate and the suspending liquid is to the MEMS tile via the microchamber 18 (FIG. 1b). The precipitate is deposited and retained within the microchamber 18 by the sieve-like action of the microcavities 17 (as shown in FIG. 1b). In other words, the microcavities filter the explosive material 16 from the supernatant fluid, the latter passing through the microcavities 17.

FIG. 1b shows the MEMS tile 5 formed from a silicon substrate 15. A microchamber 18 is micromachined into the substrate 15. The microcavities 17 form a septum 14, which is a region which caps off the explosive material 16 and can form a flyer plate upon activation of the explosive material 16. The explosive material 16 is present initially as a precipitate in suspension and is fed via the tube 4 (shown in FIG. 1a) into the microchamber 18. The explosive material 16 deposits around the microcavities 17 and forms bridges or clusters of explosive material 16 which effectively block the entrance to the microcavities. Eventually, only the solution can pass through the microcavities 17, in the direction shown 19. Thus, continued flow of the suspension eventually fills the microchamber 18 with explosive material 16.

FIG. 1c shows two MEMS tiles 20a from above and 20b viewed from the rear. Tile 20a viewed from the upper surface has a microchamber 23 which houses the explosive material (not shown). Tile 20b has a close up view 25 to more clearly see the septum 24 and the microcavities 27 formed therein, which allow the liquid to drain out of the microchamber 23. The microchamber 23 and the microcavities 27 may be formed by deep reactive ion etching.

In the above Example, the microreactor is separate from the microchamber. However, embodiments can be envisaged in which the microchamber acts as the microreactor, the first and second solutions being introduced directly into the microchamber.

Deep reactive ion etching is a preferred process for patterning silicon on the MEMS scale. The process alternates repeatedly between two modes to achieve near vertical sidewall profiles:
1. Near isotropic etch using a reactive plasma (e.g. SF₆), containing some ions which are used to bombard the wafer in a vertical direction;
2. Deposition of a chemically inert passivation layer (e.g. C₄F₈ source gas yields a highly inert fluorocarbon).

The passivation layer protects the substrate from chemical attack where it is present, but it is eroded by the physical action of ions bombarding from a vertical direction.

This allows a near isotropic etch to proceed at the bottom of trenches in the etch steps, and the feature progresses through the thickness of the layer in a stepwise fashion.

FIG. 2 shows a munition such as an artillery shell 31. The shell 31 comprises a fuse section 32 containing electronics 33, a safety and arming unit 34 (such as, for example, that shown in FIG. 4) and a main casing 35 containing an explosive train and main explosive 36. Not shown are set-back and spin sensors that typically operate after firing to allow the safety and arming unit to function subsequently.

FIG. 3 shows SEMs of silver azide (AgN₃) that have been produced at different flow rates of silver nitrate AgNO₃ and sodium azide NaN₃ at concentrations of 0.1 and 0.12 mol.dm⁻³ respectively. (See Experimental: Effects of Flow Rates below.)

FIG. 4 shows a cross sectional schematic example of a MEMS safety and arming unit according to the invention to an enlarged scale. The SAU comprises a detonator device 115 and an interrupter device 114 bonded together, assembled with an output explosive 118 which forms part of the explosive train to the final output charge i.e. warhead (not shown). The detonator device 115 comprises an igniter 111, carried on an igniter substrate 110 including a means of electrical connection 120. The microchamber 130 is formed in a substrate layer 124 and has been filled with explosive material 113 by the technique shown in FIG. 1a. The septum 121 may comprise a plurality of microcavities 122, and preferably is formed directly in the substrate layer 123, as shown. The layers 123 and 124 may alternatively be formed from a single layer.

Upon detonation of the explosive material 113, in microchamber 130, the septum 121 ruptures to form a flyer. The detonator arrangement 115 is assembled by bonding substrate 110 which carries at least one igniter 111 with a substrate layer 124 comprising the at least one explosive filled microchamber 130. A polymer bond layer 125 is used to adhere the two substrates 110 and 124.

The interrupter 114 may be formed by bonding a patterned silicon insulator wafer 129 to a cap wafer 126. The silicon on insulator wafer 129 is patterned with springs and interlock mechanism 117, and includes a shutter element 116. The cap wafer 126 is patterned with an aperture 119 to allow detonative transfer from the flyer plate 121 to the acceptor explosive 118 when the shutter 116 is moved to the armed position.

On operation of igniter 111, the explosive material 113 is caused to detonate or deflagrate, propelling the flyer (septum) 121 at high velocity towards the acceptor explosive 118. The shutter element 116, in its closed position, is capable of dissipating sufficient energy from the flyer 121 to prevent initiation of the explosive train to provide a safe condition should the initiator be activated accidentally. When the shutter element 116 is caused to move to the armed position, upon deflagration or detonation of the explosive 113, the flyer 121 travels at high speed to impact on and transfer detonation to the explosive train 118.

FIG. 5a shows an alternative cross sectional schematic example of a MEMS safety and arming unit according to the invention to an enlarged scale. The igniter 211 is formed on an igniter substrate 210 and attached to the interrupter device 230 by a polymer bond 225. In this example, the detonator device comprises a shutter element 216 with an explosive filled microchamber 213. (Note that the layer comprising the septum 221 containing the microcavities may be removed after the filling process in FIG. 1a to leave just an explosively filled microchamber; however, the preferred arrangement is shown in FIG. 5b, whereby the impact flyer layer 221 is the septum, with microcavities 222). The shutter element 216 is arranged with springs and interlocks 217 that control its movement. When the shutter element 216 is in the armed position, the igniter 211, the explosive filled microchamber 213 and the acceptor explosive 218 are aligned such that when the igniter 211 is operated the explosive filled microchamber 213 will detonate or deflagrate and cause the flyer layer 221 to impact into the acceptor explosive (explosive train) 218, leading to a transfer of detonation. When the shutter element 216 is in the safe position, moved to cause misalignment of explosive 213 and output charge 218, any functioning of the igniter 211 will not lead to detonation or deflagration of the explosive filled microchamber 213. Similarly, when the shutter element 216 is in the safe position it will be positioned such that accidental deflagration or detonation of the explosive filled microchamber 213 by an external hazard will not result in an unsafe state and will not result in detonation of the acceptor explosive 218.

Experimental

Reaction of Sodium Chloride and Silver Nitrate

A first experiment was set up using starting materials that would produce a non-explosive precipitate. Solutions of aqueous silver nitrate 0.010 mol.dm⁻³ and sodium chloride 0.012 mol.dm⁻³ were prepared. The two solutions were fed at a flow rate of 0.02 ml.min⁻¹ (1.2 ml.hr⁻¹) per feed stock into a standard T-connector, which provided the role of a microreactor chamber, to allow combination and mixing of the two solutions. The output from the microreactor was fed via a tube into the microchamber, with the microcavities in the septum layer acting as a sieve, in a set up as shown in FIG. 1a. The MEMS tile was 5×5 mm, with a depth of 1 mm. The MEMS tile was made from silicon which had approximately 100 microcavities (perforations) each of which was 35 micron diameter. The microchamber and the microcavities were both produced by a deep reactive ion etch process, as discussed with reference to FIGS. 1a, b and c.

A white precipitate was observed in the liquid flowing from the MEMS tile support, indicating that silver chloride was initially passing through the microcavities. After approximately 60 minutes, the liquid flowing from the tile did not contain any solid material. The pumps were run for 210 minutes, measured from the point at which liquid was first observed exiting the tile support, and the experiment was completed without the use of vacuum. The tile and silver chloride were dried in a vacuum desiccator overnight.

The total silver chloride produced, estimated from the time the pumps were run, was 6.0 mg and the mass retained in the microchamber of the tile was 4.4 mg. The density of the silver chloride was estimated by assuming the silver chloride above the tile was a cone of radius 0.5 mm and height 0.35 mm which, combined with the volume of the microchamber, gave a total volume of 8.77×10⁻⁴ cm³ and a density of 5.06 g.cm⁻³, 91% of the theoretical maximum.

The results are summarised in Table 1.

TABLE 1
Retention of inert silver chloride in a microchamber

| Microactivity | | Run | | AgCl re- | % of |
|---|---|---|---|---|---|
| diameter | Flow Rate | Time | Total AgCl | tained in | Theoretical |
| microns | (ml.min⁻¹) | (min) | produced (mg) | tile (mg) | Maximum |
| 35 | 0.02 | 270 | 6.0 | 4.4 | 91 |

Reaction of Sodium Azide and Silver Nitrate

The experiment was conducted using the same method as for the inert silver chloride conditions employed above. The flow rates and concentrations of the solutions of sodium azide and silver nitrate were varied (see Table 2).

TABLE 2
Effect of flow rate for silver azide formation

| | | | Reaction |
|---|---|---|---|
| | | | Chamber |
| [AgNO₃] | [NaN₃] | | Volume |
| (mol.dm⁻³) | (mol.dm⁻³) | Flow rate (cm³.hr⁻¹) | (× 10⁻⁴ cm³) |
| 0.1 | 0.12 | 1.0, 2.0, 5.0, 10.0 | 1.0 |
| 0.3 | 0.36 | 1.0, 2.0, 5.0, 10.0 | |
| 0.5 | 0.6 | 1.0, 2.0, 5.0, 10.0 | |
| 0.1 | 0.12 | 1.0, 2.0, 5.0, 10.0 | 16.1 |
| 0.3 | 0.36 | 1.0, 2.0, 5.0, 10.0 | |
| 0.5 | 0.6 | 1.0, 2.0, 5.0, 10.0 | |

Effect of Flow Rates

At each of the four flow rates investigated, the silver azide produced was spherical with evidence of secondary growth, but there was no evidence of any other polymorph present. However, the flow rate affected the morphology and particle size of the final product.

At 1 cm³.hr⁻¹, the product consisted of spherical particulates with a particle size range of 1 to 2 microns. This is shown in FIG. 3a.

At a flow rate of 2 cm³.hr⁻¹, spherical particles were formed with evidence of secondary crystal growth with the formation of necklaces (FIG. 3b) with particle sizes in the range of 0.5 to 2.0 microns.

Increasing the flow rates to 5 cm³.h⁻¹ produced spherical particles of approximately 1 to 3 microns, but the amount of secondary growth appeared to have decreased with evidence of a large number of spherical particles (FIG. 3c). These may offer the best packing performance in a MEMS microchamber, i.e. may permit a bridge of particulates to form over the microcavities, thereby allowing the solution to pass through the microcavities, but prevent and hence retain the solid particulate in the microchamber.

Further increasing the flow rate to 10 cm³.h⁻¹ reduced the particle size of the silver azide formed to approximately 0.5 to 1 microns with a large degree of secondary growth occurring (FIG. 3d). This implies that the flow rate was too fast and a considerable amount of the reaction was occurring in the outlet pipe, or after the filtration stage.

If an initial fill process was performed using relatively large particle sizes, then after a period of time the flow rate could be adjusted to reduce the particle size and effectively back fill any voids from the initial fill, to give a bimodal fill. Additionally, if the flow rates could be controlled to produce the secondary particle growth and effectively join the particles together, a very robust fill would occur with the potential of a strong interface between the silicon edges and silver azide.

Retention of Material

A series of trials were conducted to study the effect of varying the flow rate (see Table 3). The results show that more silver azide is retained in the tile cavities at lower flow rates. This observation is consistent with previous results in Table 2, which shows that larger particles sizes are obtained at lower flow rates.

TABLE 3
Retention of silver azide in microchamber

| Microactivity | | Run | Total AgN₃ | AgN₃ | % of |
|---|---|---|---|---|---|
| diameter | Flow Rate | Time | produced | retained in | theoretical |
| microns | (ml.min⁻¹) | (min) | (mg) | tile (mg) | Maximum |
| 35 | 0.01 | 270 | 4.1 | 1.26 | 31.5 |
| 35 | 0.02 | 180 | 5.4 | 0.32 | 8 |
| 35 | 0.05 | 90 | 6.75 | 0.45 | 11.25 |
| <35 | 0.02 | 180 | 5.4 | 1.00 | 25 |

The theoretical maximum mass of silver azide required to fill the well is 4.0 mg, calculated from the volume of the well and the literature density of silver chloride. The particle size of the precipitated silver azide is significantly smaller than the particle size of the precipitated silver chloride. The flow rates in Table 3 indicate that the use of slower flow rates and smaller cavities may provide microcavities which can be filled with silver azide at TMD values in the desired range.

It will be understood that the present invention has been described above purely by way of example, and modification of detail can be made within the scope of the invention. Each feature disclosed in the description and (where appropriate) the claims and drawings may be provided independently or in any appropriate combination. In particular, device aspects may be applied to method aspects and vice versa.

Moreover, the invention has been described with specific reference to MEMS detonators. It will be understood that this is not intended to be limiting and the method of the invention—in particular—may be used more generally in applications where a vessel or chamber, more specifically a micro-vessel or microchamber, needs to be filled with an explosive material.

1. A MEMS detonator comprising a substrate comprising at least one microchamber filled with an explosive material, wherein said at least one microchamber comprises a first end which is capable of receiving said explosive material and a second end comprising a septum containing a plurality of fully perforated microcavities, and wherein at least one igniter is located proximate to the explosive material.

2. A MEMS detonator according to claim 1, wherein the at least one igniter is located in thermal contact with the particulate explosive material.

3. A MEMS detonator according to claim 1, wherein the at least one microchamber has a diameter in the range of from 100 to 1500 microns.

4. A MEMS detonator according to claim 1 or claim 2, wherein the plurality of microcavities each have a diameter in the range of from 10 to 100 microns.

5. A MEMS detonator according to any one of the preceding claims, wherein the at least one igniter is located at the end distal to the septum.

6. A MEMS detonator according to any one of the preceding claims, wherein a further flyer is located on top of the septum.

7. A MEMS detonator according to any one of the preceding claims, wherein the substrate is selected from glass or silicon wafers.

8. A safety and arming unit comprising at least one MEMS detonator according to any one of the preceding claims.

9. A munition comprising at least one safety and arming unit according to claim 8.

10. A method of filling a MEMS detonator comprising the steps of:
i) selecting two or more solutions that are capable of interacting to form an explosive material as a precipitate,
ii) passing the two or more solutions in separate channels into a microreactor,
iii) causing the combining and/or mixing of the two or more solutions,
iv) causing precipitation of said explosive material, and
v) depositing said precipitate into a microchamber comprising a septum containing a plurality of microcavities, and allowing the supernatant solution to pass through the microcavities.

11. A method according to claim 10, wherein the two or more solutions are a first solution of a non-explosive compound and a second solution of a non-explosive compound, which when combined in the microreactor undergo a chemical precipitation reaction to form said explosive material.

12. A method according to claim 10, wherein the two or more solutions are a first solution of a dissolved explosive material and a second solution of a solvent capable of causing precipitation of the dissolved explosive material from said first solution, such that upon combining in the microreactor they form a precipitate of said explosive material.

13. A method according to any one of claims 10 to 12, wherein the two or more solutions are aqueous ionic salts which under go a chemical precipitation reaction to provide an explosive non-soluble salt.

14. A method according to any one of claims 10 to 12, wherein the particulate explosive material is consolidated in the microchamber to at least 40% theoretical maximum density.

15. A method according to claim 14, wherein the range is of from 60 to 95% theoretical maximum density.

16. A method according to any one of claims 10 to 15, wherein the two or more solutions are pumped into the chamber at an elevated pressure.

17. A method according to claim 16, wherein the two or more solutions are pumped at a pressure in the range of from 1 to 100 atmospheres.

18. A method of preparing a primary explosive comprising the steps of:
i) selecting two or more solutions that are capable of interacting to form said precipitated explosive material,
ii) passing the two or more solutions in separate channels into a microreactor,
iii) causing the combining and/or mixing of the two or more solutions,
iv) causing precipitation of said primary explosive material.

19. A method according to claim 18, wherein the two or more solutions are a first solution of a non-explosive compound and a second solution of a non-explosive compound, which when combined in the microreactor undergo a chemical precipitation reaction to form said explosive material.

20. A method according to claim 18, wherein the two or more solutions are a first solution of a dissolved explosive material and a second solution of a solvent capable of causing precipitation of the dissolved explosive material from said first solution, such that upon combining in the microreactor they form a precipitate of said explosive material.

21. A method of preparing a primary explosive comprising the steps of: selecting two or more solutions which, when combined, interact to form an explosive material as a precipitate; passing the two or more solutions in separate channels into a microreactor; and combining and/or mixing the two or more solutions in the microreactor so that precipitation takes place.

22. A method of filling a MEMS detonator comprising the steps of: selecting two or more solutions which, when combined, interact to form an explosive material as a precipitate; passing the two or more solutions in separate channels into a microreactor; combining and/or mixing the two or more solutions in the microreactor so that precipitation takes place; passing the precipitate and supernatant fluid into a microchamber comprising a septum containing a plurality of microcavities such that the precipitate is deposited in the microchamber; and allowing the supernatant fluid to pass through the microcavities

23. A precursor unit for a MEMS detonator comprising a substrate comprising at least one microchamber, wherein said at least one microchamber comprises a first end which is capable of receiving said explosive material and a second end comprising a septum containing a plurality of fully perforated microcavities.

24. The use of a MEMS detonator according to any one of claims 1 to 7 in a munition.

25. Any use, method, kit of parts or device substantially as hereinbefore described, with reference to the accompanying drawings.

26. Any novel feature, or combination of features, hereinbefore described, with reference to the accompanying drawings
